(19) United States
(12) Patent Application Publication
(10) Pub. No.: US 2003/0059973 A1
(43) Pub. Date: Mar. 27, 2003

(54) Micromechanical switch and method of manufacturing the same

(75) Inventor: Michael J. Trainor, Horley (GB)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/241,082

(22) Filed: Sep. 11, 2002

(30) Foreign Application Priority Data
Sep. 21, 2001 (GB) 0122752.9

(51) Int. Cl. H01L 21/00

(52) U.S. Cl. 438/52

(57) ABSTRACT

A micromechanical switch is disclosed comprising a conductive beam (14, 14′) partially suspended above a substrate (10), at least one contact electrode (12, 12′) adjacent the conductive beam and at least one control electrode (13, 13′) adjacent the conductive beam; wherein, upon application of a potential at the control electrode, the beam is deflectable in the plane of the substrate whereby the conductive beam may be selectively contacted with the contact electrode to create an electrical path between them. In particular, the conductive beam may be elongate in the plane of the substrate and has an elongate cross section in a direction perpendicular to the substrate.

### FIELD OF INVENTION

This invention relates to a micromechanical switch and to a method of manufacturing the same.

### BACKGROUND TO INVENTION

U.S. Pat. No. 5658698 discloses a microstructure such as an electrostatic actuator comprising a substrate, a patterned beam member suspended over the substrate with an air-space therebetween and supporting structure for suspending the beam member over the substrate. The microstructure is prepared by using a sacrificial layer which is removed to form the space between the beam member and the substrate. Deflection of the beam is in a plane perpendicular to the substrate and in response to electrostatic attraction between the beam member (or a conductive part thereof) and a gate/control electrode located adjacent the beam as a result of applying a potential to the gate/control electrode.

In a conventional such switch, the energy stored in the cantilever capacitance varies rapidly with separation between gate/control electrodes and the cantilever. Once sufficient energy is stored, the switch closes suddenly and hysterically as the value of the separation is much smaller when the switch is closed. The “off to on” voltage therefore typically differs from the “on to off” voltage.

U.S. Pat. No. 5818093 discloses a semiconductor accelerometer device having a gate suspended over a semiconductor substrate wherein the gate is rotatably mounted in the plane of the substrate.

### OBJECT OF INVENTION

It is an object of the invention to provide an improved micromechanical switch and a method of manufacturing the same.

### SUMMARY OF INVENTION

According to the present invention, there is provided a micromechanical switch comprising a conductive beam partially suspended above a substrate, at least one contact electrode adjacent the conductive beam and at least one control electrode adjacent the conductive beam. Upon application of a potential at one of the control electrodes, the beam is deflectable in the plane of the substrate whereby the conductive beam may be selectively contacted with a contact electrode to create an electrical path between them.

Such a configuration of switch enables a switch where the variation of stored electrical energy with the displacement of the beam to be much less rapid, and therefore switching can be made more controllable.

Ideally, the conductive beam is elongate in the plane of the substrate with an elongate cross section in a direction perpendicular to the substrate in order to render the beam less resilient to the attractive forces of the control electrodes so easing movement in the plane of the substrate.

Also provided in accordance with the present invention is a method of manufacturing such a micromechanical switch comprising the steps of forming a sacrificial layer on a substrate; forming a conductive beam on the substrate; removing the sacrificial layer to leave the conductive beam partially suspended above the substrate; and, adjacent the conductive beam, forming at least one control electrode and at least one contact electrode.

Either thick film printing techniques, thin film deposition techniques or a combination thereof may be used to manufacture the switch. Also, to minimize the number of process steps: for thick film, the conductive beam and at least one of the electrodes may be formed by a thick film printing technique including during the same printing step; or for thin film, a conductive layer may be deposited using a thin film deposition technique and patterned to form both the conductive beam and at least one of the electrodes.

### BRIEF DESCRIPTION OF DRAWINGS

The present invention will now be described, by way of example only, with reference to following figures in which:

FIGS. 1a and 1b, 2a and 2b and 3a and 3b are respective side and plan views illustrating a method of manufacturing a micromechanical switch according to the present invention; and

FIG. 4 shows an alternative configuration of a micromechanical switch according to the present invention.

### DETAILED DESCRIPTION

It should be noted that the above figures are not to scale. Rather, the relative dimensions and parts of these figures have either been exaggerated or reduced in size for reasons of clarity and to aid understanding of the invention. Also, the same reference signs are used to refer to corresponding or similar features in different embodiments.

A micromechanical switch according to the present invention may be manufactured as follows:

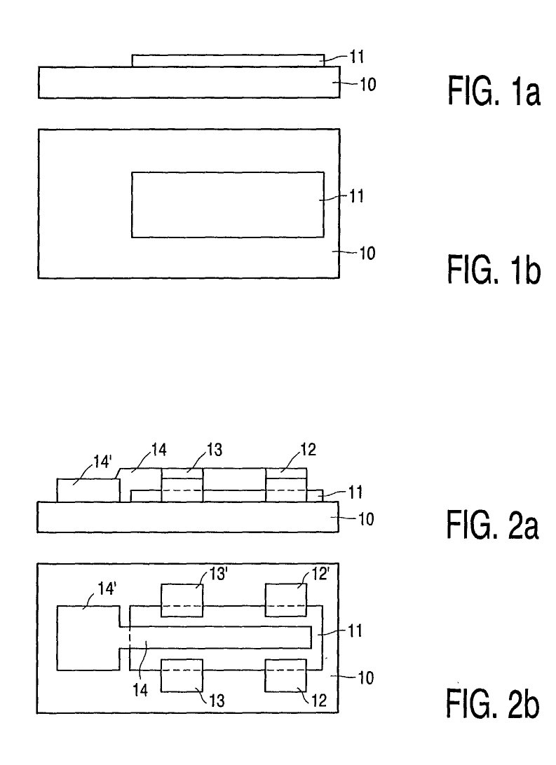

(1) On a substrate 10 (which may be glass, silicon or another material and optional capped by a layer of silicon oxide or silicon nitride and the like), a sacrificial layer 11 of polymer photoresist is deposited and patterned as illustrated in FIGS. 1a and 1b.

(2) Then, as illustrated in FIGS. 2a and 2b, a conductive layer such as Aluminum (or alternatively Aluminum alloy, Chromium or other conductor) may then be deposited over the substrate 10, partially on the substrate and partially on the sacrificial layer 11. The conductive layer may then be patterned to form a conductive beam 14, 14′ and, located adjacent the beam, control and contact electrodes.

(3) As illustrated in FIGS. 3a and 3b, the sacrificial layer may then be removed using conventional techniques to leave the conductive beam partially suspended over the substrate.

The resulting switch operates in a manner whereby a potential applied to either control electrode 13 or 13′ caused the beam to be attracted to that electrode and eventually contact a corresponding contact electrodes 12 or 12′, thereby establishing an electrical path between the beam and that contact electrode. The base of the beam and the contact and control electrodes may then be connected to external circuitry (not shown) for operation as a switch for that circuitry. Also, a matrix array of such switches may be used.

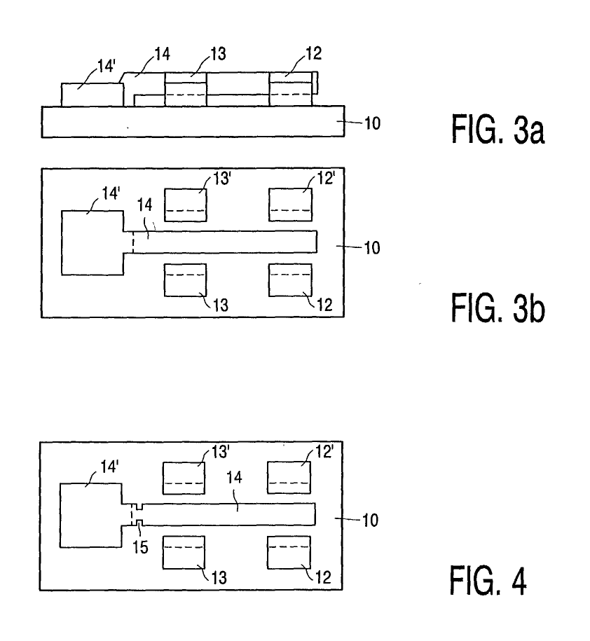

An alternative configuration of a micromechanical switch according to the present invention is shown in FIG. 4 in which the beam 14 is thinner at a pivot point 15 close to the base of the beam 14′. This provides the conductive beam with an elongate cross section in a direction perpendicular to the substrate, and thus renders the beam less resilient to the attractive forces of the control electrodes so easing movement in the plane of the substrate.

The manufacture or conventional “cantilever” type micromechanical switches is well known and many of the techniques, materials and considerations for manufacturing them, including precise process conditions, are also relevant for the manufacture of a micromechanical switch according to the present invention. For example, see the following documents incorporated herein by reference: article “Micromechanical Membrane Switches on Silicon” by K. E. Petersen (IBM J Res. Development, Vol. 23, Nov. 4, 1979); U.S. Pat. Nos. 5638946 and 5658698 (especially column 4, line 34 to column 5, line 50 for a discussion on sacrificial layers); and PCT patent application WO96/16435. Accordingly, such techniques, materials or considerations have not been exhaustively described in the present text.

1. A micromechanical switch comprising a conductive beam partially suspended above a substrate, at least one contact electrode adjacent the conductive beam and at least one control electrode adjacent the conductive beam; wherein, upon application of a potential at one of the control electrodes, the beam is deflectable in the plane of the substrate whereby the conductive beam may be selectively contacted with a contact electrode to create an electrical path between them.

2. A switch according to claim 1 wherein the conductive beam is elongate in the plane of the substrate and has an elongate cross section in a direction perpendicular to the substrate.

3. A method of manufacturing a micromechanical switch comprising the steps of:
forming a sacrificial layer on a substrate;
forming a conductive beam on the substrate;
removing the sacrificial layer to leave the conductive beam partially suspended above the substrate; and
adjacent the conductive beam, forming at least one control electrode and at least one contact electrode,
wherein, upon application of a potential at the control electrode, the beam is deflectable in the plane of the substrate whereby the conductive beam may be selectively contacted with the contact electrode to create an electrical path between them.

4. A method according to claim 3 wherein the conductive beam is elongate in the plane of the substrate and has an elongate cross section in a direction perpendicular to the substrate.

5. A method according to claim 3 wherein the conductive beam and at least one of the electrodes are formed by a thick film printing technique during the same printing step.

6. A method according to claim 3 wherein a conductive layer is deposited using a thin film deposition technique and patterned to form both the conductive beam and at least one of the electrodes.

7. A micromechanical switch manufactured by a method according to claim 3.
